(19) United States
(12) Patent Application Publication
(10) Pub. No.: US 2009/0213367 A1
(43) Pub. Date: Aug. 27, 2009

(54) Transmissive element

(76) Inventor: Mino Green, London (GB)

Correspondence Address: Fay Sharpe LLP, 1228 Euclid Avenue, 5th Floor, The Halle Building, Cleveland, OH, 44115, US

(21) Appl. No.: 11/629,261

(22) PCT Filed: Jun. 13, 2005
(86) PCT No.: PCT/GB05/02340

§ 371 Date: Aug. 15, 2008

(30) Foreign Application Priority Data
Jun. 14, 2004 (GB) 0413243.7

(51) Int. Cl. G01N 21/03; H01L 33/00; H01B 5/14; G02B 5/00; C23C 14/22; B05D 5/06

(52) U.S. Cl. 356/244; 257/72; 174/126.4; 359/894; 204/192.1; 427/162; 257/E33.068

(57) ABSTRACT

A transmissive element and a method for production thereof is provided, the element comprising a perforated layer (22) of conductive material (20). Applications include electrochromic windows, energy efficient architectural windows, and touch screen panels, for example.

The invention relates to a transmissive element.

A number of applications require the provision of an optically transmissive conductive element in the form of “conductive glass”, that is a transparent conductive coating on a transparent substrate. These applications include touch panel contacts, electrodes for LCD and electrochromic displays and windows, energy conserving architectural windows, defogging aircraft and automobile windows, heat reflecting or heatable coatings, photovoltaic solar cells, filters, tunable, variable transmission/reflection filters, one-way mirrors, anti-reflection coatings and anti-static window coatings. The current materials of choice for these purposes are indium tin oxide (ITO) and fluoride doped tin oxide (FTO). The first offers a sheet resistance of 10 ohms per square (the units are dimension independent) for a transmission of visible light of around 80%. Transmission of approximately 90% of visible light can be achieved with ITO, but at a price of an increased sheet resistance of larger than 100 ohms per square.

Higher conductivity at a given transmission may be achieved by a coating consisting of a perforated conductive film with an array of holes. Known techniques for making such perforated films involve lithographic methods using deep UV electron beam and focused ion beam techniques, and are hence very costly and applicable to only small areas of material. Generally these methods achieve only a small fractional area (F) covered by holes, and thus only relatively low transmissions. Furthermore, it is important that the holes are sufficiently small such that they are not perceived by the eye but rather such that the film appears uniform in texture.

The invention is set out in the claims.

By relying on Island Lithography as described in more detail below, the present invention provides a method for fabricating perforated conductive films which is cost effective and applicable to large areas of material. Using this method, a sheet resistance as low as one or two ohms per square may be achieved at a transmission rate of about 80% for visible light.

A specific embodiment of the invention is now discussed, by way of example only and with reference to the accompanying figures, in which like reference numerals refer to like features and in which:

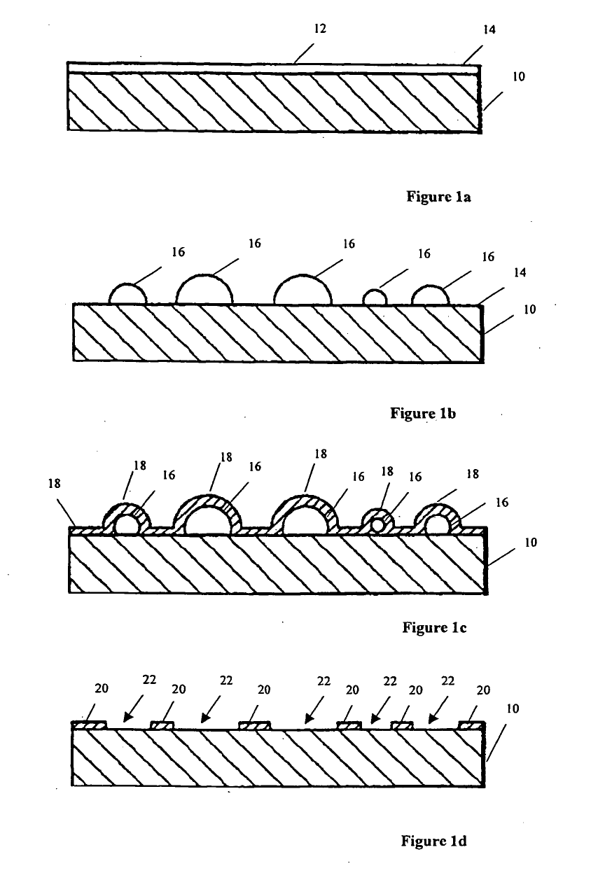

FIGS. 1a to d illustrate a method for forming perforated conductive film according to an embodiment of the invention:

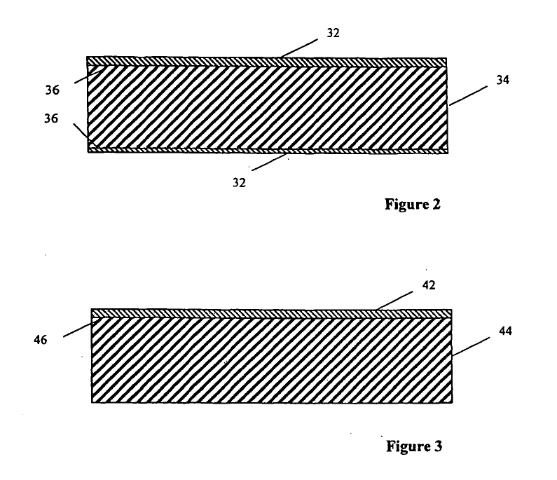

FIG. 2 shows an electrochromic window element fabricated using conductive glass with a perforated conductive film according to an embodiment of the invention; and

FIG. 3 shows a heat reflective window element or a self-heating window element according to an embodiment of the invention.

In overview, the invention uses Island Lithography to form a perforated film. Briefly, Island Lithography consists in applying a thin film of a water soluble solid on a substrate and causing the soluble solid to reorganise into somewhat disordered array of hemispherical islands. Island Lithography is described in patent application WO01/13414 of Mino Green, which is herewith incorporated by reference. In particular Island Lithography is used to form a perforated film of resist material by coating the substrate surface and islands with a resist material and subsequently removing the coated islands. The perforated film of resist material is then used in a subsequent etching process. Island Lithography is further described in M. Green and S. Tsuchiya, J. Vac. Sci & Tech. B 17 (1999) 2074 and S. Tsuchyia, M. Green, R. Syms, Electrochemical & Solid State Letters 3 (2000) 44. In the present invention Island Lithography is used to form a perforated conductive layer on transmissive substrate using a surprising new effect of the invention by modifying the method of Island Lithography to obtain an optically transmissive conductive layer. “Transmissive” refers to the transmission of electromagnetic radiation with, for example, wavelength in the UV, IR or visible spectrum; a material capable of transmitting any wavelength of electromagnetic radiation is considered to be transmissive. Similarly, a material capable of reflecting any wavelength of electromagnetic radiation is considered to be reflective.

In a specific embodiment of the invention, an optically transparent conducting element (for example “conducting glass”) is manufactured using the method described in detail below. In summary, the method comprises depositing a film of cesium chloride 12 onto a hydrophilic surface 14 of an optically transparent substrate 10, exposing the film to water vapour of controlled partial pressure thus forming an array of cesium chloride (CsCl) islands on the surface, depositing a layer of conductive material over the surface and islands and finally removing the coated islands thus leaving an electrically conductive layer with an array of holes or perforations corresponding to the islands. Evidently, a resistive, insulator or semi-conductor layer may be used in place of a conductive layer.

In the specific embodiment the optically transparent substrate 10 is made of glass or silica and has a surface area of, for example, 10 cm², although larger or smaller substrates could evidently be used. The glass substrate is cleaned using a three stage (H₂O₂/NH₄OH/H₂O) etch, resulting in a hydrophilic surface 14 with a small (smaller than a few degrees) contact angle with water. The substrate is placed in a vacuum chamber and a layer of CsCl 12 (thickness 1 to 200 nm, for example 23 nm) is vacuum deposited by evaporation on to the glass surface. The chamber pressure of the vacuum chamber is between 5×10⁻⁵ to 1×10⁻³ Pa and the evaporation rate is in the range of 0.2-50 angstrom per second. The coated substrate is removed from the vacuum chamber and immediately placed in a controlled atmosphere chamber (relative humidity 15 to 70%, for example 40%) for a given time, for example 10 minutes. The exposure to the vapour in the controlled atmosphere chamber results in reorganisation or coagulation of the CsCl film into a distribution of hemispheric islands 16 with a mean diameter of 10 nm to larger than 1000 nm, more preferably 50-400 nm, for example 190 nm, and a distribution whose width at half height is 10 to 20% of the mean diameter. The fractional area of the island may be as large as 80 to 90%, but lower fractional areas of, for example, 20% may also be possible. It should be noted that as a simple alternative to using a controlled atmosphere chamber, the coated substrate may simply be exposed to the relative humidity of the ambient atmosphere, if it is of a suitable value.

Following the formation of islands, the substrate and islands are coated with a layer 18 of conductive material, preferably metal, for example, aluminium, chromium, gold, and/or silver. In a particular embodiment, a dual coating of a first layer (closest to the substrate) of chromium and a second layer of gold or silver is applied. The chromium coating (evaporated from a chromium covered rod) ensures good adhesion to the glass substrate and easy lift off over the CsCl islands while the second layer of silver or gold (or any other suitable metal) can be chosen according to the specific requirements. For example, silver and gold may be evaporated from an electrically heated molybdenum boat.

The conducting layer may be formed by vacuum evaporation or sputtering, as appropriate. In the case of vacuum evaporation, this will normally be done at a chamber pressure of between 5×10⁻⁵ and 1×10⁻³ Pa, and an evaporation rate of 0.2-50 angstroms per second and a temperature of −30 to +100 degrees C. In the case of sputtering, a plasma gas (e.g. Ar and/or O₂) would be used in conjunction with a power source of 30 to 200 watts for a period of 0.5 to 30 minutes at a chamber pressure of 1 to 50 m Torr. As a rule of thumb, the layer of conductive material should have a thickness of less than half the average diameter of the holes or perforations.

The optical and electrical properties of the perforated layer can be tuned by a suitable choice of conductive material, layer thickness and/or average diameter of the holes and the distribution of the hole diameter. In practice this is achieved by tuning the various parameters of the method steps described above, for example tuning thickness of the cesium chloride layer, the timing of the various steps or the relative humidity used for island formation.

Following the conductive coating step, the islands are removed using an ultrasonic agitation process, which can be carried out under a range of different conditions. The frequency may be in the range of 24 to 100 kHz, power 13 to 130 W and power density of 0.05 to 0.5 W/cm². The sample is placed in a container with water, which is placed in an ultrasonic bath and agitated for 15 minutes or such a time as necessary for the metal layer covering even the smaller CsCl islands to be detached. This leaves a perforated sheet 20 of conductive material with an irregular array of holes or cavities 22 in place of the CsCl islands and a lace or lattice work of metal coating surrounding the holes.

In an alternative embodiment, it is envisaged that the evaporation of a conductive material is carried out at a grazing angle of incidence, varying between 15 to 90 degrees to the substrate surface, which, after removal of the CsCl islands, results in elliptical holes with a major/minor access axis ratio depending on the grazing angle. Generally a ratio of up to 4-1 may be achieved.

Alternatively, elongated CsCl islands can be achieved by using an anisotropically structured surface such as fine scratches in one direction only, on which the salt solution is then deposited. This could be used for application to the rubbed polymer layer of a liquid crystal cell where the rubbing could be in the metal and have a uniform dielectric covering it. This could give thinner, more uniform thickness variation across a cell.

If the substrate surface is prepared with an isotropic mesh of scratches, the CS CL solution would flow into the scratches. Island Lithography could then be used to create a very fine, continuous, electrically conductive mesh which could result in even lower fractional areas F and thus higher transmission.

It has previously been shown that transmission of an ordered array of sub-wavelength diameter holes is in fact super transmitting by as much as a factor of two in certain ranges of diameter to wavelength ratios. This effect where more light is transmitted by a perforated thin metal film than would be predicted from considering only the fractional area of the perforations is referred to as super-luminescence. For example, a chromium film perforated by a regular hexagonal lattice of holes (F=0.227, hole diameter 500 nm) gives a transmission efficiency of 0.55 at a diameter to wavelength ratio of 1 rising to a peak value at 1.76 at a diameter to wavelength ratio of 0.42. For a comparable square array, the comparable values of transmission efficiency are 0.43 and 1.45, respectively. Compared to this a disordered or irregular array according to the invention (silver film of layer thickness 168 nm and chromium layer of layer thickness 9 nm, average hole diameter 340 nm, width at half height of hole diameter distribution 67 nm, and a fractional hole area of 0.28) achieved a transmission efficiency of 1.3 at a diameter to wavelength ratio of 0.4 rising to 2.1 at a diameter to wavelength ratio of 0.5. From this it can been seen that an irregular array of holes according to the invention, which is much easier to manufacture, not only achieves comparable results, but even out-performs regular arrays structures. The hole diameter may be smaller or comparable to the desired wavelength of transmission and the fractional area F may be in the region of 0.5 to 0.85.

It will be appreciated that embodiments of the invention can be used in a number of applications. In a first application, an optically transparent element 32 according to the invention can be used as a transparent conductor in electrochromic windows. FIG. 2 shows an electrochromic window with a central portion 34 comprising an ion storage, ion conductor/electrolyte and electrochromic layer sandwiched between the two conductive 32 elements, such that the conductive layer 36 of the element is in contact with the centre portion. The conducting layer of the elements is connected to a lower voltage source (not shown in the drawing) thus allowing a potential difference to be applied across the centre portion. When a potential difference is applied across the two conducting layers, it draws ions from the ion storage layer through the ion conducting layer into the electrochromic layer, thus darkening (or “colouring”) the windows. The darkening is reversed by reversing the voltage and thus driving the ions back into the ion storage layer.

Two further applications use a compound of a conductive element 42 according to the invention 42 and a window portion 44 as shown in FIG. 3. In a first application, this may be used as an energy efficient architectural window, as the connective layer will tend to reflect more light of the infrared spectrum than of the visible spectrum. This will tend to keep a building warm in the winter by keeping heat inside the building and cool in the summer by reflecting infrared from the sun into the environment. Notably, the transmission and reflection coefficients of the window can be tuned by tuning, for example, the size distribution of the perforations in the conductive layer or by selecting different materials for the conductive layer, as set out above.

In another implementation, by connecting the conducting (and of course, resistive) layer 46 to a current source, the window may be heated by running a current through the conductive element. This is useful in defogging aircraft or automobile windows or door mirrors without the presence of visible resistive wires in current window heating systems. As the conversion from current heating depends on the resistance of the conductive element, a coating using a metal with higher resistivity, for example chromium itself Cr/Ni alloy, cuprothal, alchrome or inconel are advantageous for this application. Of course, a conductive element need not necessarily be applied to the surface of the window, but may, alternatively, be embedded within the window material. Naturally, the same applies to the infrared reflective window application.

A further application of the technique of the invention is to produce an array of dots rather than an array of perforations. This can be done by partially reversing the order of the method steps described above, that is the substrate is first covered with the conductive material, a layer of a soluble solid is then applied to the conductive layer and made to form an array of islands as described above. The array of islands can then be used as a resist for an etching process which leaves only the conductive material underneath an island intact. The islands can then subsequently be removed as described above, or by any other convenient method.

By using a metal-dielectric-metal stack for the conductive layer, a structure with millions of nano-stacks per square centimetre could be produced. The stacks could act as gates for the transistors of a TFT display with hundreds of transistors per pixel, giving redundancy and an increased yield for TFT manufacturers.

A further application of a substrate covered with a perforated sheet of conducting material according to the inventions is in Raman Spectroscopy, where the perforations serve as a receptacle for a Raman Spectroscopy sample. In such an application, the substrate can conveniently be formed from a metal oxide, the conductive layer being a metal.

It will be appreciated that individual features of the embodiments and applications can be varied, interchanged or juxtaposed as necessary.

It is further understood that the invention extends to embodiments in which the substrate is not glass but some other suitable material, such as silica or borosilica or other material of desired refractive index, for example 1.5255 at 546 nm and 1.5230 at 588 nm wavelength. Other materials are of course possible, for example silicon is transparent in the IR and sapphire from UV through visible and into IR.

Furthermore, it is possible to extend this method to other chemical systems. For example, water and potassium chloride would be suitable. Also ethanol for the vapour and sodium iodide as the re-organising resist material would be possible. The user of vapour of other solvents is also envisaged, in which case CsCl would be replaced with a suitable lyophilic (with respect to the solvent used) solid and a substrate surface which is lyophilic for the solvent used would need to be employed. Using different solvents would result in different surface energies for the solution and lead to different size and spacing distributions.

If a substrate with a lyophobic surface were to be used, the surface would need to be treated to make it lyophilic. This may be achieved in a number of ways, for example by oxidising the substrate surface. Finally, although all specific embodiments use CsCl for forming the islands any other suitable lyophilic solid or other Island Lithography technique may be used.

1. A method of fabricating a transmissive element comprising forming a perforated film on a transmissive substrate by Island Lithography.

2. A method as claimed in claim 1 in which the transmissive element is optically transmissive and fabricated to transmit light in the UV, IR, visible or other part of the electromagnetic spectrum.

3. A method as claimed in claim 1 in which the element is transparent.

4. A method as claimed in claim 1 in which the film comprises an electrically conductive, resistive, insulator or semiconductor material.

5. A method as claimed in claim 1, comprising the step of:
(a) depositing a film of a soluble solid onto a lyophilic surface of the substrate;
(b) exposing the film to solvent vapour, forming an array of islands on the surface;
(c) depositing a layer of a conductive material on the surface and islands;
(d) removing the coated island, leaving a conductive layer with an array of holes corresponding to the islands.

6. A method as claimed in claim 5 in which the soluble solid is a salt, and the solvent is a water.

7. A method as claimed in claim 6 in which the solid is cesium chloride.

8. A method as claimed in claim 1, in which the substrate comprises one or more of the group of silicon, saphire, glass, silica and borosilica.

9. A method as claimed in any of claim 4 in which the conductive material comprises a metal.

10. A method as claimed in claim 9 in which the metal comprises one or more of the group of aluminium, silver, gold, copper and chromium.

11. A method as claimed in any of claim 4 in which the conductive material is deposited by evaporation, sputter deposition or chemical vapour deposition.

12. A method as claimed in claim 5 in which the deposition of conductive material is achieved by directing a vapour stream at a grazing angle of incidence to the substrate, such that an island casts a shadow in which there is no vapour deposition and the holes remaining in the film after removal of the islands are elongated.

13. A method as claimed in claim 5, in which the removal of the coated islands comprises submerging the element in an ultrasonic agitation bath filled with solvent.

14. A transmissive element comprising a transmissive substrate and a perforated film supported by the substrate, the film comprising an irregular array of perforations.

15. An element as claimed in claim 14 for transmitting radiation of wavelength λ, the perforations having a mean diameter smaller than or substantially equal to λ, wherein the radiation may be optical radiation in the UV, IR or visible spectrum.

16. An element as claimed in claim 14 in which the perforated film comprises a conductive material.

17. An element as claimed in claim 16, in which the conductive material comprises a metal.

18. An element as claimed in claim 17, in which the metal comprises one or more of the group of aluminium, silver, gold, copper and chromium.

19. An element as claimed in claim 16, wherein the perforated film comprises a first and second metallic layer the first metallic layer being of a different metal from the second metallic layer.

20. An element as claimed in claim 19, wherein the first layer is closer to the substrate than the second layer and the first layer comprises chromium.

21. An element as claimed in claim 14, the element being transparent.

22. An element as claimed in claim 14, in which the substrate comprises one or more of the group of glass, borosilica and silica.

23. An element as claimed in claim 14 in which the perforations have substantially circular cross section.

24. An element as claimed in claim 23 in which the diameter of cavities is in the range of 0.7 to 0.1 microns.

25. An element as claimed in claim 23 in which the thickness of the conductive layer is smaller than half the average diameter of the perforations.

26. An element as claimed in claim 14, in which the fractional area covered by the perforations is in the range of 0.5 to 0.85.

27. An element as claimed in claim 14 formed by a method as claimed in any of claims 1 to 13.

28. An electrochromic window comprising an optically transmissive element as claimed in claim 14 or fabricated according to a method as claimed in claim 1.

29. A selectively reflecting window comprising an optically transmissive element as claimed in claim 14 or fabricated according to a method as claimed in claim 1.

30. A heatable window comprising an optically transmissive element as claimed in claim 14 or fabricated according to a method as claimed in claim 1.

31. A sample holder for use in Raman Spectroscopy, the sample holder comprising an optically transmissive element as claimed in claim 14 or fabricated according to a method as claimed in claim 1.

32. A transmissive element comprising an irregular array of dots fabricated using Island Lithography.

33. A transmissive element comprising a transmissive substrate and an irregular array of nano-stacks supported on the substrate, the nano-stacks comprising a dielectric layer sandwiched between first and second metal layers.

34. A TFT display comprising an element as claimed in claim 33.

35. An element as claimed in claim 14 in which the cavities are of elliptical cross-sections.

36. A device comprising a transmissive perforated film having an irregular array of perforations defining a distribution over the size of the perforations, the transmissive perforated film being mounted on a transmissive or reflective substrate.

37. A device as claimed in claim 36, wherein the array and the distribution are arranged such that the film is super-luminescent.

38. A device as claimed in claim 36, wherein the film comprises a conductor and/or resistive material.

39. A device as claimed in claim 36, wherein the film comprises a metal.

40. A method as claimed in claim 1, further comprising the step of isotropically or anisotropically scratching the substrate surface.
